(19) United States
(12) Patent Application Publication
(10) Pub. No.: US 2021/0264888 A1
(43) Pub. Date: Aug. 26, 2021

(54) Flexural Ultrasonic Transducer

(71) Applicant: The University of Warwick, Coventry (GB)

(72) Inventors: Steve DIXON, Coventry (GB); Lei KANG, Coventry (GB); Andrew FEENEY, Coventry (GB)

(73) Assignee: The University of Warwick, Coventry (GB)

(21) Appl. No.: 17/261,682

(22) PCT Filed: Jul. 16, 2019
(86) PCT No.: PCT/GB2019/051976

§ 371 Date: Jan. 20, 2021

(30) Foreign Application Priority Data
Jul. 20, 2018 (GB) 1811922.2

(51) Int. Cl. G10K 9/22; B06B 1/06; G10K 9/122; H01L 41/053

(52) U.S. Cl. CPC G10K 9/22; B06B 1/06; B06B 2201/58; H01L 41/053; B06B 2201/55; G10K 9/122

(57) ABSTRACT

A flexural ultrasonic transducer is disclosed. The ultrasonic transducer comprises a sealed case which includes a flexible membrane and which defines a sealed cavity. The sealed case has an inside and an outside. The ultrasonic transducer comprises an active element, for example, a piezoelectric element, inside the sealed case supported on the flexible membrane. The ultrasonic transducer includes a liquid in the cavity. The sealed case includes a resilient portion between the inside and outside of the case for allowing equalization of pressure between the inside and the outside of the case. The resilient portion may comprise resilient walls or a thin-wall section, the flexible membrane or the case.

### FILED

The present invention relates to a flexural ultrasonic transducer, particularly, but not exclusively, a flexural ultrasonic transducer comprising a piezoelectric element.

### BACKGROUND

A flexural ultrasonic transducer is type of ultrasound sensor which operates on the principle of a bending membrane at resonance to produce an ultrasound wave, and/or a membrane bending in response to an incident ultrasonic wave to detect an ultrasonic wave. A piezoelectric element, which is typically bonded to an inwardly-facing surface of a membrane, is used to generate a bending motion of the membrane at ultrasonic frequencies, dominating the vibration response of the transducer. Reference is made to S. Dixon, L. Kang, M. Ginestier, C. Wells, G. Rowlands, and A. Feeney: “The electro-mechanical behaviour of flexural ultrasonic transducers”, Applied Physics Letters, volume 110, page 223502 (2017), which is incorporated herein by reference.

A flexural ultrasonic transducer is highly efficient for both transmission and detection of ultrasound, where vibrational response is only slightly affected by the loading medium, compared to the mechanical resonance characteristics of the membrane. It only requires low voltages (for example less than 1 V) to excite ultrasonic vibration of the membrane and produces signals that are easily detectable using the same transducer or a second flexural ultrasonic transducer. Flexural ultrasonic transducers tend to be cheap, low power, and robust and so can be used in many applications, including industrial metrology.

Flexural ultrasonic transducers have been used extensively as proximity sensors, for example, in car-parking systems, and in underwater sonar applications. Currently-available commercial flexural ultrasonic transducers are designed to operate in air or in fluids at ambient pressure. There is industry demand for measurement and transmission of ultrasound in domestic ultrasonic water meters which operate up to around 20 bar (2,000 kPa), gas meters up to 300 bar (30,000 kPa), and hydraulic flow systems above 300 bar (30,000 kPa). Currently, however, there is no flexural type ultrasonic technology available which can withstand these conditions.

### SUMMARY

According to a first aspect of the present invention there is provided a flexural ultrasonic transducer. The flexural ultrasonic transducer comprises a sealed case which includes a flexible membrane and which defines a sealed cavity. The sealed case has an inside and an outside. The flexural ultrasonic transducer comprises an active element inside the sealed case supported on the flexible membrane. The flexural ultrasonic transducer comprises a liquid (such as mineral oil) in the cavity (such that occupied region(s) of the cavity are filled by the liquid). The sealed case includes a resilient portion between the inside and outside of the case for allowing equalization of pressure between the inside and the outside of the case.

The area of the resilient portion and/or the degree to which the resilient portion can be displaced are sufficiently large to allow a sufficiently large volume change. For example, the resilient portion of the case is able to flex sufficiently to change the volume of the cavity by at least 1 part in 10⁵.

The sealed case may include bellows having a resilient wall or walls forming the resilient portion of the case. For example, a resilient wall can take the form of a concertinaed wall which can be compressed or extended.

The sealed case may include a thin-walled section forming the resilient portion of the case. The thin-walled section may be formed as a step or recess in a thicker wall.

The resilient portion may comprise, consist of or essentially consist of the flexible membrane. In other words, the flexible membrane may provide the resilient portion. The resilient portion may comprise, consist of or essentially consist of the case. For example, the walls of the case may be made sufficiently thin to flex. Thus, no bellows or thin-wall section may be needed.

The flexural ultrasonic transducer may be capable of operating in an ambient pressure less than or equal to 1 bar (100 kPa) to greater than or equal to 10 bar (1,000 kPa) or greater than or equal to 300 bar (30,000 kPa).

The active element may be a piezoelectric element supported on the membrane. Thus, the transducer may be a piezoelectric transducer.

The active element may be a ferromagnetic element supported on the membrane and the transducer may further comprise a coil. Thus, the transducer may be a magnetostrictive transducer. The coil is preferably disposed in the case.

### BRIEF DESCRIPTION OF THE DRAWINGS

Certain embodiments of the present invention will now be described, by way of example, with reference to the accompanying drawings, in which:

FIG. 1 is a cross-sectional view of a first flexural ultrasonic transducer;

FIG. 2 is a cross-sectional view of a second flexural ultrasonic transducer;

FIG. 3 is a cross-sectional view of a third flexural ultrasonic transducer; and

FIG. 4 is a cross-sectional view of a fourth flexural ultrasonic transducer.

### DETAILED DESCRIPTION OF CERTAIN EMBODIMENTS

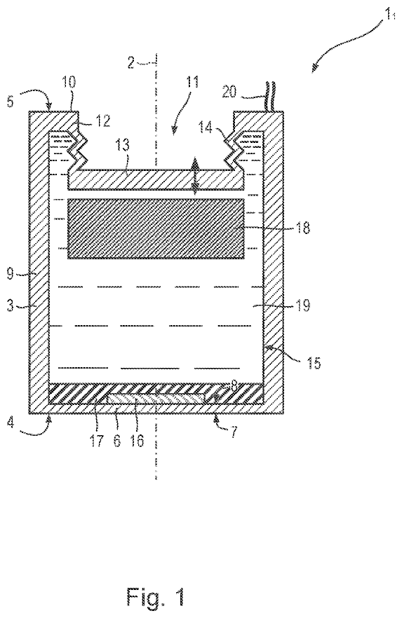

Referring to FIG. 1, a first flexural ultrasonic transducer 1₁ is shown. The ultrasonic transducer 1₁ is capable of operating at high pressures, for example, above 10 bar (1,000 kPa), up to as high as 300 bar (30,000 kPa) or more.

The ultrasonic transducer 1₁ is generally cylindrical about a central axis 2 and comprises a liquid-tight sealed metal case 3 (or “housing”) formed from a suitable material, such as aluminium, titanium, or steel. The case 3 has first and second ends 4, 5 (herein also referred to as the “front” and “back” respectively).

The case 3 includes a flexible membrane 6 having outer and inner faces 7, 8, a cylindrical side wall 9, and cap 10. The cap 10 is part of the case 3 and is not simply made from silicone or other sealant.

The flexible membrane 6 behaves approximately as an edge-clamped, thin plate. The operating frequency of the flexible membrane 6 depends on the material type, diameter, and thickness of the membrane 6. Reference is made to A. Feeney, L. Kang, G. Rowlands and S. Dixon: “The Dynamic Performance of Flexural Ultrasonic Transducers”, Sensor, volume 18, pages 270 (2018). The classical solutions of thin, edge-clamped circular plates can then be used to define the thickness of the flexible membrane, through calculation of the resonant modes in the ultrasonic transducer design process. The case 3 can be made as either a single piece, or from separate pieces (for example, a front piece, a back piece, and a cylindrical side wall piece) joined together, for example, by adhesive bonding or laser welding. The flexible membrane 6 and the cylindrical side wall 9 may be joined, for example, by adhesive bonding or laser welding. Using the classical solutions of thin, edge-clamped circular plates, a flexible membrane 9 made from aluminium, with a thickness of 0.40 mm and a diameter of 10 mm, will result in an ultrasonic transducer with a fundamental mode operating frequency around 40 kHz. The width of the cylindrical side wall 9 is typically in the order of 1 mm and reference is made to T. J. R. Eriksson, S. N. Ramadas, and S. M. Dixon: “Experimental and simulation characterisation of flexural vibration modes in unimorph ultrasound transducers”, Ultrasonics, volume 65, pages 242-248 (2016). The cap 10 includes resilient portion of the case in the form of bellows ii extending inwardly from an annular collar 12. The bellows ii include a central plate 13 and a resilient, concertinaed side wall 14 joining the central plate 13 to the collar 12. The side wall 14 is reversibly compressible or extendable in a direction along the central axis 2 thereby allowing the central plate 13 to move axially.

The case 3 may be formed from multiple pieces which are assembled and sealed to form a liquid-tight case. Different pieces may be formed from different materials. For example, the cylindrical side wall 9 can be made from titanium and joined to a flexible membrane 6 fabricated from steel, for example using adhesive bonding, laser welding or other suitable joining technique.

The case 3 defines a sealed cavity 15 which contains a piezoelectric element 16 mounted, for example bonded using an adhesive (not shown), on the inner face 8 of the flexible membrane 6, a layer 17 of electrically-insulating material overlying the piezoelectric element 16, and a disk 18 of ultrasound-absorbing material proximate the back 5 of the transducer. The insulating layer 17 may be omitted. The rest of the cavity 15 is filled with a non-conductive liquid 19, such as a mineral oil or Novec®. If an electrically-insulating layer 17 is used, then liquid 19 may be conductive. A set of wires 20 are electrically connected (for example, by soldering) to the piezoelectric element 16 and pass through the walls of the case 7. For clarity, the wires 20 are not shown within the case 3.

The bellows 11 can enable equalisation of pressure between the inside and outside of the case 3 by allowing the volume of the cavity 15 to change. Small changes in volume, for example, 1 part in 10⁵, can help to equalise pressure.

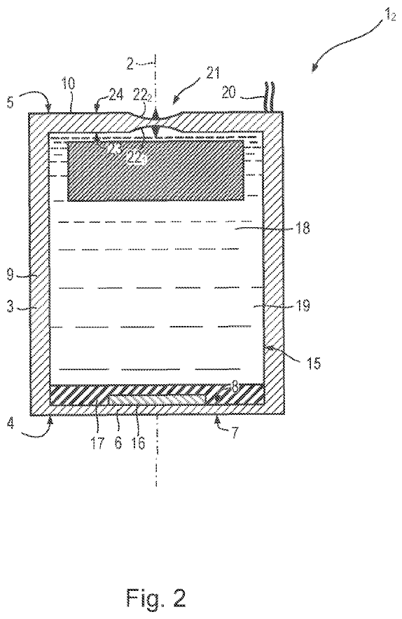

Referring to FIG. 2, a second flexural ultrasonic transducer 1₂ is shown. The ultrasonic transducer 1₂ is capable of operating at high pressures, for example, above 10 bar (1,000 kPa) and up to as high as 300 bar (30,000 kPa) or more.

The second flexural ultrasonic transducer 1₂ is similar to the first flexural ultrasonic transducer 1₁ except that instead of bellows 11, the cap 10 generally takes the form of a plate which includes a thin-walled section 21 comprising first and second opposite-facing concave recesses 22₁, 22₂ extending into the plate from opposite sides 23, 24 of the plate 10. The thin-walled section 21 is sufficiently pliable that it can equalise pressure between the inside and outside of the case 3. The thin-walled section 21 can be incorporated into the side wall 4 or even the flexible membrane 6. The flexible membranes of devices currently available, such as those described in Eriksson et al., ibid., Dixon et al., ibid., and Feeney et al., ibid., are unable to equalize pressure. The second flexural ultrasonic transducer 1₂ comprises a thin-walled section 21 which is can flex sufficiently to equalize pressure.

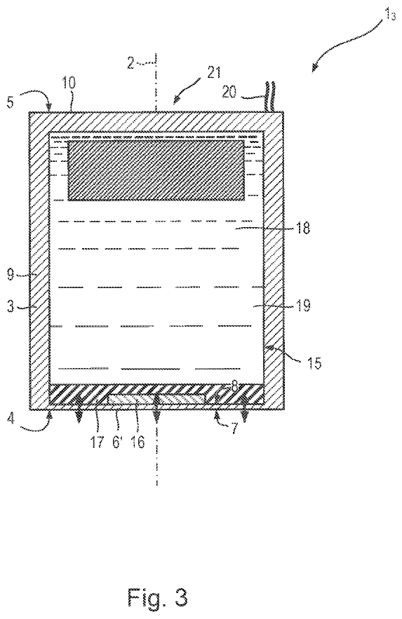

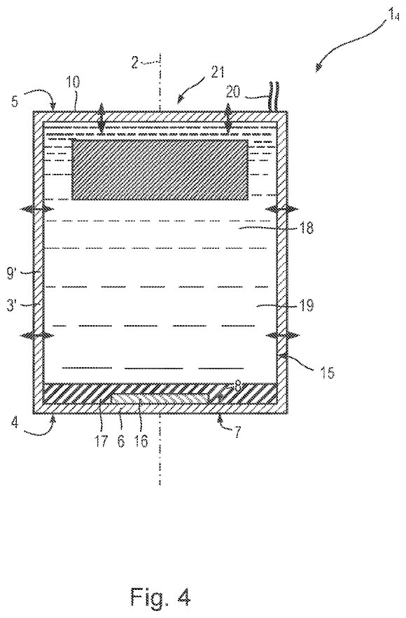

Referring to FIGS. 3 and 4, the resilient portion of the case 3 may be provided in part or solely by a thinner flexible membrane 6′ and/or by a thinner case 3′. In particular, the walls of the case 3 may be made sufficiently thin and/or made from a more compliant material such that the majority or all of the case ₃ can deform. Additionally or alternatively, the wall(s) of the case 3 may be extended so as to increase compliance. For example, the cylindrical wall 9′ made taller. If the wall(s) are made sufficiently compliant, then they can bow inwards and/or outwards. Thus, a flexural ultrasonic transducer 1₃, 1₄ may be constructed in such a way that there is no additional feature, other than the membrane 6′ itself and/or the case 3′, that is configured to deform to equalise the pressure inside the transducer to that outside the transducer. Because the volume change of the liquid 19 inside the transducer is very small, even at high pressures inside the liquid, the strain induced in the membrane may be small enough to still allow the membrane 6, 6′ to flex sufficiently to generate or detect ultrasonic waves.

### MODIFICATIONS

It will be appreciated that various modifications may be made to the embodiments hereinbefore described. Such modifications may involve equivalent and other features which are already known in the design, manufacture and use of flexural ultrasonic transducers and component parts thereof and which may be used instead of or in addition to features already described herein. Features of one embodiment may be replaced or supplemented by features of another embodiment.

The transducer need not be cylindrical but can be elliptical or polygonal in plan view.

The membrane may have a non-uniform thickness or may be preformed into a shape that is not flat.

A combination of two or more different resilient portions may be used.

The transducer may be a magnetostrictive transducer. Thus, the active element may be ferromagnetic element and need not be piezoelectric.

Although claims have been formulated in this application to particular combinations of features, it should be understood that the scope of the disclosure of the present invention also includes any novel features or any novel combination of features disclosed herein either explicitly or implicitly or any generalization thereof, whether or not it relates to the same invention as presently claimed in any claim and whether or not it mitigates any or all of the same technical problems as does the present invention. The applicants hereby give notice that new claims may be formulated to such features and/or combinations of such features during the prosecution of the present application or of any further application derived therefrom.

1. A flexural ultrasonic transducer comprising:
a sealed case which includes a flexible membrane and which defines a sealed cavity, the sealed case having an inside and an outside;
an active element inside the sealed case supported on the flexible membrane; and
a liquid in the cavity;
wherein the sealed case includes a resilient portion between the inside and outside of the case for allowing equalization of pressure between the inside and the outside of the case.

2. The flexural ultrasonic transducer of claim 1, wherein the resilient portion of the case is able to flex sufficiently to change volume of the cavity by at least 1 part in 10⁵.

3. The flexural ultrasonic transducer of claim 1, wherein the resilient portion comprises the flexible membrane.

4. The flexural ultrasonic transducer of claim 1, wherein the sealed case includes bellows including resilient walls forming the resilient portion of the case.

5. The flexural ultrasonic transducer of claim 1, wherein the sealed case includes a thin-walled section forming the resilient portion of the case.

6. The flexural ultrasonic transducer of claims 1, wherein the resilient portion comprises the sealed case.

7. The flexural ultrasonic transducer of claims 1, capable of operating in an ambient pressure exceeding 1,000 kPa.

8. The flexural ultrasonic transducer claim 1, wherein the active element is a piezoelectric element supported on the flexible membrane.

9. The flexural ultrasonic transducer of claims 1, wherein the active element is a ferromagnetic element supported on the membrane and the transducer further comprises a coil.
